(19) United States
(12) Patent Application Publication
(10) Pub. No.: US 2026/0160834 A1
(43) Pub. Date: Jun. 11, 2026

(54) SYSTEM AND METHOD FOR SWEEPING MAGNETIC FLUX FROM SUPERCONDUCTING INTEGRATED CIRCUITS

(71) Applicants: Hypres Inc., Elmsford, CT (US); Sun Magnetics Pty, Stellenbosch, (ZA)

(72) Inventors: Oleg MUKHANOV, Putnam valley, NY (US); Daniel Yohannes, Stamford, CT (US); Coenrad Fourie, Stellenbosch (ZA); Kyle Jackman, Stellenbosch (ZA); llya Sochnikov, Storrs, CT (US)

(21) Appl. No.: 18/981,215

(22) Filed: Dec. 13, 2024

Related U.S. Application Data
(60) Provisional application No. 63/609,828, filed on Dec. 13, 2023.

(51) Int. Cl. G01R 33/00; G01R 33/035; H10N 60/80; H10N 60/82; H10N 69/00

(52) U.S. Cl. CPC G01R 33/0011; G01R 33/0354; H10N 60/805; H10N 60/82; H10N 69/00

(57) ABSTRACT

A system and method for eliminating flux trapping in superconducting integrated circuits. An array of control current lines is provided, closely coupled thermally and magnetically with a superconducting integrated circuit. These control lines are configured to produce both heat and magnetic fields, with amplitudes and sequences of control currents designed to sweep magnetic flux away from the superconducting circuits at cryogenic operating temperatures. Verification may be obtained using SQUID magnetic sensors located close to the circuits. Similar methods may be applied to all superconducting integrated circuits which are sensitive to weak magnetic fields, including classical single-flux-quantum circuits, sensor arrays, and quantum computing circuits comprised of superconducting qubits. This system is scalable to superconducting circuits with up to millions of superconducting devices. The control currents may be configured to operate under automated feedback control.

### CROSS REFERENCE TO RELATED APPLICATIONS

The present application is a non-provisional of, and claims benefit of priority under 35 U.S.C. § 119(e), from U.S. Provisional Patent Application No. 63/609,828 , filed Dec. 13, 2023, the entirety of which is expressly incorporated herein by reference.

### FIELD OF THE INVENTION

The present invention relates to the field of superconducting integrated circuits, and more particularly to removing trapped magnetic flux from superconducting integrated circuits.

### INCORPORATION BY REFERENCE

Citation or identification of any reference herein, or any section of this application shall not be construed as an admission that such reference is available as prior art. The disclosure of each publication and patent listed or referenced herein are hereby incorporated by reference in their entirety in this application, and shall be treated as if the entirety thereof forms a part of this application. Such references are provided for their disclosure of technologies as may be required to enable practice of the present invention, to provide written description for claim language, to make clear applicant's possession of the invention with respect to the various aggregates, combinations, permutations, and subcombinations of the respective disclosures or portions thereof (within a particular reference or across multiple references) in conjunction with the combinations, permutations, and subcombinations of various disclosure provided herein, to demonstrate the technological non-abstract nature of the inventions claimed, and for any other purpose. Except as expressly indicated, the scope of the invention is inclusive, and therefore the disclosure of a technology or teaching within these incorporated materials is intended to encompass that technology or teaching as being an option of, or an addition to, other disclosure of the present invention. Likewise, the combination of incorporated teachings consistent with this disclosure is also encompassed. The citation of references is intended to be part of the disclosure of the invention, and not merely supplementary background information. While cited references may be prior art, the combinations thereof and with the material disclosed herein is not admitted as being prior art.

The incorporation by reference does not extend to teachings which are inconsistent with the invention as expressly described herein as being essential. The incorporated references are rebuttable evidence of a proper interpretation of terms, phrases, and concepts employed herein by persons of ordinary skill in the art. No admission is made that any incorporated reference is analogous art to the issues presented to the inventor, and the selection, combination, and disclosure of these disparate teachings is itself a part of the invention herein disclosed.

### BACKGROUND OF THE INVENTION

The scale and complexity of superconducting integrated circuits (ICs) has increased substantially in recent years, with applications to sensors, digital data processors, classical computing, and quantum computing. These are comprised of thousands of Josephson junctions, integrated with inductors, capacitors, and resistors on the same chip. These are generally fabricated from superconducting thin films of niobium (Nb), niobium nitride (NbN), and aluminum (especially for quantum computing circuits) and are designed to operate at temperatures less than 5 K. However, these films are very sensitive to weak magnetic fields, typically associated with multiple superconducting vortices, each having quantized magnetic flux Φ₀=h/2e=2×10⁻¹⁵ Wb, which may be trapped in the superconducting films comprising the integrated circuits. These trapped fluxons are known collectively as the flux trapping problem, and a variety of techniques have been developed over the years to reduce this problem, including by magnetic shielding, thermal cycling above the critical temperature T_{c}, and patterning moats in the superconducting films. The flux-trapping problem is of major concern in a wide variety of superconducting integrated circuits, including classical superconducting digital processors, quantum superconducting systems, and large arrays of superconducting sensors.

See, for example, the following patents, published patent applications, and non-patent literature, incorporated herein by reference in their entirety:
U.S. Pat. No. 4,392,148, “Moat-guarded Josephson devices”.
U.S. Pat. No. 4,409,579, “Superconducting magnetic shielding apparatus and method.”
U.S. Pat. No. 5,164,696, “Apparatus for eliminating trapping of magnetic flux from an object”.
U.S. Pat. No. 5,173,620, “Device for eliminating trap of magnetic flux in a superconduction circuit”.
U.S. Pat. No. 8,644,898, “Superconducting device having a pattern of engineered defects for controlling magnetic flux”.
U.S. Pat. No. 9,913,414, “Method & apparatus of implementing a magnetic shield flux sweeper”.
U.S. Pat. No. 9,982,935, “Cryogenic system with rapid thermal cycling”.
U.S. Pat. No. 11,064,637, “System & method for magnetic shielding for a superconducting computing system”.
U.S. Pat. No. 11,417,821, “Superconductor ground-plane patterning geometries that attract magnetic flux”.
US 2021/0068320, “Shielding for superconducting devices”.
US 2022/0198310, “Semi-active magnetic shielding for qubit unit components of quantum computing apparatuses”.
US 2023/0270020, “Superconducting chip package with improved magnetic shielding”.
U.S. Patent and Published Application Nos. 2023/0004851; 2018/0240033; 2012/0157319; 2011/0065585; 2004/0098443; U.S. Pat. Nos. 11,417,821; 9,520,180; 6,469,880; 6,332,324; 5,323,344; 5,287,058; 5,173,620; 5,164,696; 5,053,707; 5,051,787; 4,392,148; 4,051,393; 3,706,064
“Heat Transfer Module User's Guide,” Stockholm, 2018.
T. M. Fujimaki, T. Yamada, Y. Yamanashi, P. Heejoung and N. Yoshikawa, “Bit-serial single flux quantum microprocessor CORE,” IEICE transactions on electronics, vol. 91, no. 3, pp. 342-349, 2008.
Al Luhaibi, A. Glatz and J. B. Ketterson, “Driven responses of periodically patterned superconducting films,” Phys. Rev. B, vol. 106, no. 22, p. 224516, December 2022.
D. Hernández and D. Domínguez, “Dissipation spots generated by vortex nucleation points in mesoscopic superconductors driven by microwave magnetic fields,” Phys. Rev. B, vol. 77, no. 22, p. 224505, June 2008.
I. Bezuglyj, V. A. Shklovskij, B. Budinská, B. Aichner, V. M. Bevz, M. Y. Mikhailov, D. Y. Vodolazov, W. Lang and O. V. Dobrovolskiy, “Vortex jets generated by edge defects in current-carrying superconductor thin strips,” Phys. Rev. B, vol. 105, no. 21, p. 214507, June 2022.
I. Blair and D. P. Hampshire, “Time-Dependent Ginzburg-Landau Simulations of the Critical Current in Superconducting Films and Junctions in Magnetic Fields,” IEEE Transactions on Applied Superconductivity, vol. 28, pp. 1-5, 2018.
L. Pankratov and B. Spagnolo, “Suppression of timing errors in short overdamped Josephson junctions,” Physical review letters, vol. 93, no. 17, p. 177001, 2004.
M. Herr, C. A. Mancini, N. Vukovic, M. F. Bocko and M. J. Feldman, “High-speed operation of a 64-bit circular shift register,” IEEE transactions on applied superconductivity, vol. 8, no. 3, pp. 120-124, 1998.
M. Herr, M. J. Feldman and M. F. Bocko, “Timing jitter and bit errors in a 64-bit circular shift register,” IEEE transactions on applied superconductivity, vol. 9, no. 2, pp. 3721-3724, 1999.
Matlashov, et al., “AC defluxing of SQUIDs”, IEEE Trans. Appl. Supercond., vol. 27, art. 1601605 (2017).
Mitrovic and E. G. Friedman, “Thermal Modeling of Rapid Single Flux Quantum Circuit Structures,” IEEE Transactions on Electron Devices, vol. 69, pp. 2718-2724, 2022.
H. Venter and C. J. Fourie, “Initial Numerical Simulation of the Thermodynamic Behaviour of a Superconducting Circuit,” in 2019 IEEE International Superconductive Electronics Conference (ISEC), 2019.
Oripov and S. M. Anlage, “Time-dependent Ginzburg-Landau treatment of rf magnetic vortices in superconductors: Vortex semiloops in a spatially nonuniform magnetic field,” Phys. Rev. E, vol. 101, no. 3, p. 033306, March 2020.
Venter, “Development of a thermal analysis tool for superconducting circuits,” Stellenbosch: Stellenbosch University, 2021-03.
Xu, J. Franklin, H.-Y. Yang, F. Tafti and I. Sochnikov, “Directional field-dependence of tunable magnetic domains in noncentrosymmetric ferromagnetic Weyl semimetal CeAlSi,” in 2021 IEEE International Magnetic Conference (INTERMAG), 2021.
A. a. V. N. Mancini, A. M. Herr, K. Gaj, M. F. Bocko and M. J. Feldman, “RSFQ circular shift registers,” IEEE transactions on applied superconductivity, vol. 7, no. 2, pp. 2832-2835, 1997.
J. Fourie and K. Jackman, “Experimental Verification of Moat Design and Flux Trapping Analysis,” IEEE Transactions on Applied Superconductivity, vol. 31, pp. 1-7, 2021.
J. Fourie and K. Jackman, “High-fidelity circuit simulation of AQFP circuits through compact models extracted from layout,” Journal of Physics: Conference Series, vol. 2323, p. 012034, August 2022.
J. Fourie and K. Jackman, “Software Tools for Flux Trapping and Magnetic Field Analysis in Superconducting Circuits,” IEEE Transactions on Applied Superconductivity, vol. 29, pp. 1-4, 2019.
J. Fourie, K. Jackman, M. M. Botha, S. Razmkhah, P. Febvre, C. L. Ayala, Q. Xu, N. Yoshikawa, E. Patrick, M. Law, Y. Wang, M. Annavaram, P. Beerel, S. Gupta, S. Nazarian and M. Pedram, “ColdFlux Superconducting EDA and TCAD Tools Project: Overview and Progress,” IEEE Transactions on Applied Superconductivity, vol. 29, pp. 1-7, 2019.
J. Fourie, O. Wetzstein, T. Ortlepp and J. Kunert, “Three-dimensional multi-terminal superconductive integrated circuit inductance extraction,” Superconductor Science and Technology, vol. 24, p. 125015, November 2011.
K. Teh and Y. Okabe, “A novel global self-timing methodology for BSFQ circuits,” IEEE transactions on applied superconductivity, vol. 13, no. 2, pp. 543-546, 2003.
Davino, J. Franklin and I. Sochnikov, “Millikelvin-compatible apparatus for studies of quantum materials under uniaxial stress,” AIP Advances, vol. 9, p. 125244, December 2019.
Stošić, D. Stošić, T. Ludermir, B. Stošić and M. V. Milošević, “GPU-advanced 3D electromagnetic simulations of superconductors in the Ginzburg-Landau formalism,” Journal of Computational Physics, vol. 322, pp. 183-198, 2016.
Marchiori, L. Ceccarelli, N. Rossi, G. Romagnoli, J. Herrmann, J.-C. Besse, S. Krinner, A. Wallraff and M. Poggio, “Magnetic imaging of superconducting qubit devices with scanning SQUID-on-tip,” Applied Physics Letters, vol. 121, p. 052601, August 2022.
Persky, I. Sochnikov and B. Kalisky, “Studying Quantum Materials with Scanning SQUID Microscopy,” Annual Review of Condensed Matter Physics, vol. 13, pp. 385-405, 2022.
Sardella, A. L. Malvezzi, P. N. Lisboa-Filho and W. A. Ortiz, “Temperature-dependent vortex motion in a square mesoscopic superconducting cylinder: Ginzburg-Landau calculations,” Phys. Rev. B, vol. 74, no. 1, p. 014512, July 2006.
R. Berdiyorov, M. V. Milošević and F. M. Peeters, “Spatially dependent sensitivity of superconducting meanders as single-photon detectors,” Applied Physics Letters, vol. 100, p. 262603, June 2012.
R. Gerber, C. J. Fourie, W. J. Perold and L. C. Muller, “Design of an asynchronous microprocessor using RSFQ-AT,” IEEE Transactions on Applied Superconductivity, vol. 17, no. 2, pp. 490-493, 2007.
A. Sadovskyy, A. E. Koshelev, C. L. Phillips, D. A. Karpeyev and A. Glatz, “Stable large-scale solver for Ginzburg-Landau equations for superconductors,” Journal of Computational Physics, vol. 294, pp. 639-654, 2015.
S. Aranson and L. Kramer, “The world of the complex Ginzburg-Landau equation,” Rev. Mod. Phys., vol. 74, no. 1, p. 99-143, February 2002.
S. Veshchunov, et al., “Optical manipulation of single flux quanta,” Nature Communications, vol. 7, September (2016).
S. Veshchunov, W. Magrini, S. V. Mironov, A. G. Godin, J.-B. Trebbia, A. I. Buzdin, P. Tamarat and B. Lounis, “Optical manipulation of single flux quanta,” Nature Communications, vol. 7, September 2016.
A. Delport, K. Jackman, P. l. Roux and C. J. Fourie, “JoSIM—Superconductor SPICE Simulator,” IEEE Transactions on Applied Superconductivity, vol. 29, pp. 1-5, 2019.
Franklin, J. Bedard and I. Sochnikov, “Versatile Millikelvin Hybrid Cooling Platform for Superconductivity Research,” IEEE Transactions on Applied Superconductivity, vol. 33, pp. 1-3, 2023.
R. Clem and K. K. Berggren, “Geometry-dependent critical currents in superconducting nanocircuits,” Phys. Rev. B, vol. 84, no. 17, p. 174510, November 2011.
R. Clem, Y. Mawatari, G. R. Berdiyorov and F. M. Peeters, “Predicted field-dependent increase of critical currents in asymmetric superconducting nanocircuits,” Phys. Rev. B, vol. 85, no. 14, p. 144511, April 2012.
R. Kirtley and J. P. Wikswo, “Scanning Squid Microscopy,” Annual Review of Materials Science, vol. 29, pp. 117-148, 1999.
J. R. Kirtley, “Fundamental studies of superconductors using scanning magnetic imaging,” Reports on Progress in Physics, vol. 73, p. 126501, November 2010.
Gaj, C.-H. Cheah, E. G. Friedman and M. J. Feldman, “Functional modeling of RSFQ circuits using Verilog HDL,” IEEE transactions on applied superconductivity, vol. 7, no. 2, pp. 3151-3154, 1997.
Gaj, E. G. Friedman and M. J. Feldman, “Timing of multi-gigahertz rapid single flux quantum digital circuits,” in High Performance Clock Distribution Networks, Springer, 1997, pp. 135-164.
Gaj, E. G. Friedman, M. J. Feldman and A. Krasniewski, “A clock distribution scheme for large RSFQ circuits,” IEEE Transactions on Applied Superconductivity, vol. 5, no. 2, pp. 3320-3324, 1995.
K. Gaj, Q. Herr and M. Feldman, “Parameter variations and synchronization of RSFQ circuits,” Conference Series-Institute Of Physics, vol. 148, pp. 1733-1736, 1995.
K. Jackman and C. J. Fourie, “Fast Multicore Fast Henry and a Tetrahedral Modeling Method for Inductance Extraction of Complex 3D Geometries,” in 2015 15th International Superconductive Electronics Conference (ISEC), 2015.
K. Jackman and C. J. Fourie, “Flux Trapping Analysis in Superconducting Circuits,” IEEE Transactions on Applied Superconductivity, vol. 27, pp. 1-5, 2017.
K. Jackman and C. J. Fourie, “Flux trapping experiments to verify simulation models,” Superconductor Science and Technology, vol. 33, p. 105001, August 2020.
K. Jackman and C. J. Fourie, “Multipole accelerated magnetic field calculations for superconducting circuits,” Superconductor Science and Technology, vol. 32, p. 015011, November 2018.
K. Jackman and C. J. Fourie, “Tetrahedral Modeling Method for Inductance Extraction of Complex 3-D Superconducting Structures,” IEEE Transactions on Applied Superconductivity, vol. 26, pp. 1-5, 2016.
K. K. Likharev and V. K. Semenov, “RSFQ logic/memory family: a new Josephson-junction technology for sub-terahertz-clock-frequency digital systems,” IEEE Transactions on Applied Superconductivity, vol. 1, no. 1, pp. 3-28, 1991.
K. Suzuki, R. Hosomizu, S. Adachi, U. Kawabe and K. Tanabe, “Investigation of flux trapping into moats with various moat depths by a scanning SQUID microscope,” Physica C: Superconductivity, Vols. 392-396, pp. 1446-1450, 2003.
K. Tanaka, T. Morooka, A. Odawara, Y. Mawatari, S. Nakayama, A. Nagata, K. Ikeda, K. Chinone and M. Koyanagi, “Study of trapped flux in a superconducting thin film-observation by scanning SQUID microscope and simulation,” IEEE Transactions on Applied Superconductivity, vol. 11, pp. 230-233, 2001.
Bishop-Van Horn, “pyTDGL: Time-dependent Ginzburg-Landau in Python,” Computer Physics Communications, vol. 291, p. 108799, 2023.
Bishop-Van Horn, E. Mueller and K. A. Moler, “Vortex dynamics induced by scanning SQUID susceptometry,” Phys. Rev. B, vol. 107, no. 22, p. 224509, June 2023.
Kramer and R. J. Watts-Tobin, “Theory of Dissipative Current-Carrying States in Superconducting Filaments,” Phys. Rev. Lett., vol. 40, no. 15, p. 1041-1044, April 1978.
L. Peng and C. Cai, “Finite Element Treatment of Vortex States in 3D Cubic Superconductors in a Tilted Magnetic Field,” Journal of Low Temperature Physics, vol. 188, p. 39-48, March 2017.
Alnæs, J. Blechta, J. Hake, A. Johansson, B. Kehlet, A. Logg, C. Richardson, J. Ring, M. E. Rognes and G. N. Wells, “The FEniCS project version 1.5,” Archive of numerical software, vol. 3, 2015.
C. de Andrade, et al., “Flux flushing in superconducting niobium films,” IEEE 14th International Superconductive Electronics Conference (ISEC 2013).
Dorojevets, P. Bunyk and D. Zinoviev, “FLUX chip: Design of a 20 -GHz 16-bit ultrapipelined RSFQ processor prototype based on 1.75-$\mu$m LTS technology,” IEEE transactions on applied superconductivity, vol. 11, no. 1, pp. 326-332, 2001.
M. Jeffery, T. Van Duzer, J. R. Kirtley and M. B. Ketchen, “Magnetic imaging of moat-guarded superconducting electronic circuits,” Applied Physics Letters, vol. 67, pp. 1769-1771, September 1995.
M. Machida and H. Kaburaki, “Direct simulation of the time-dependent Ginzburg-Landau equation for type-II superconducting thin film: Vortex dynamics and V-I characteristics,” Phys. Rev. Lett., vol. 71, no. 19, p. 3206-3209, November 1993.
M. Maezawa, I. Kurosawa, M. Aoyagi, H. Nakagawa, Y. Kameda and T. Nanya, “Rapid single-flux-quantum dual-rail logic for asynchronous circuits,” IEEE transactions on applied superconductivity, vol. 7, no. 2, pp. 2705-2708, 1997.
M. Maezawa, I. Kurosawa, Y. Kameda and T. Nanya, “Pulse-driven dual-rail logic gate family based on rapid single-flux-quantum (RSFQ) devices for asynchronous circuits,” Advanced Research in Asynchronous Circuits and Systems, 1996. Proceedings., Second International Symposium on, pp. 134-142, 1996.
Bunyk, K. Likharev and D. Zinoviev, “RSFQ technology: Physics and devices,” International journal of high speed electronics and systems, vol. 11, no. 1, pp. 257-305, 2001.
Bunyk, M. Leung, J. Spargo and M. Dorojevets, “FLUX-1 RSFQ microprocessor: Physical design and test results,” IEEE transactions on applied superconductivity, vol. 13, no. 2, pp. 433-436, 2003.
Holmvall, N. Wall Wennerdal, M. Håkansson, P. Stadler, O. Shevtsov, T. Löfwander and M. Fogelström, “SuperConga: An open-source framework for mesoscopic superconductivity,” Applied Physics Reviews, vol. 10, p. 011317, March 2023.
Geng, et al., “Sweeping of trapped flux in superconducting films by a micro-heat-flushing method”, J. Appl. Phys., vol. 72, pp. 2411-2417 (1992).
J. Watts-Tobin, Y. Krahenbuhl and L. Kramer, “Nonequilibrium theory of dirty, current-carrying superconductors: phase-slip oscillators in narrow filaments near T c,” Journal of Low Temperature Physics, vol. 42, p. 459-501, March 1981.
R. Robertazzi, et al., “Flux trapping experiments in single flux quantum shift registers,” IEEE Transactions on Applied Superconductivity, vol. 7, pp. 3164-3167, (1997).
Narayana, et al., “Evaluation of Flux Trapping in Superconducting Circuits,” IEEE Transactions on Applied Superconductivity, vol. 19, pp. 640-643, 2009.
Golod, L. Morlet-Decarnin and V. Krasnov, “Word and bit line operation of a 1×1 um2 superconducting vortex-based memory,” Nature Communications, vol. 14, no. 4926, pp. 1-8, 2023.
T. Jabbari and E. Friedman, “Stripline topology for flux mitigation”, IEEE Trans. Appl. Supercond., vol. 33, art. 1500604 (2023).
T. S. Alstrøm, M. P. Sørensen, N. F. Pedersen and S. Madsen, “Magnetic Flux Lines in Complex Geometry Type-II Superconductors Studied by the Time Dependent Ginzburg-Landau Equation,” Acta Applicandae Mathematicae, vol. 115, p. 63-74, August 2010.
T. Winiecki and C. S. Adams, “A Fast Semi-Implicit Finite-Difference Method for the TDGL Equations,” Journal of Computational Physics, vol. 179, pp. 127-139, 2002.
K. Semenov and M. M. Khapaev, “How Moats Protect Superconductor Films From Flux Trapping,” IEEE Transactions on Applied Superconductivity, vol. 26, pp. 1-10, 2016.
D. Gropp, H. G. Kaper, G. K. Leaf, D. M. Levine, M. Palumbo and V. M. Vinokur, “Numerical Simulation of Vortex Dynamics in Type-II Superconductors,” Journal of Computational Physics, vol. 123, pp. 254-266, 1996.
W.-K. Kwok, U. Welp, A. Glatz, A. E. Koshelev, K. J. Kihlstrom and G. W. Crabtree, “Vortices in high-performance high-temperature superconductors,” Reports on Progress in Physics, vol. 79, p. 116501, September 2016.
Ando, R. Sato, M. Tanaka, K. Takagi, N. Takagi and A. Fujimaki, “Design and Demonstration of an 8-bit Bit-Serial RSFQ Microprocessor: CORE e4,” IEEE Transactions on Applied Superconductivity, vol. 26, no. 5, pp. 1-5, 2016.
Kameda, S. Polonsky, M. Maezawa and T. Nanya, “Primitive-level pipelining method on delay-insensitive model for RSFQ pulse-driven logic,” in Advanced Research in Asynchronous Circuits and Systems, 1998. Proceedings. 1998 Fourth International Symposium on, 1998.
Polyakov, et al., “3D active demagnetization of cold magnetic shields”, IEEE Trans. Appl. Supercond., vol. 21, pp. 724-727 (2011).
Y. Yamanashi, H. Imai and N. Yoshikawa, “Influence of Magnetic Flux Trapped in Moats on Superconducting Integrated Circuit Operation,” IEEE Transactions on Applied Superconductivity, vol. 28, pp. 1-5, 2018.
J. Deng, N. Yoshikawa, S. R. Whiteley and T. V. Duzer, “Data-driven self-timed RSFQ digital integrated circuit and system,” IEEE Transactions on Applied Superconductivity, vol. 7, no. 2, pp. 3634-3637, 1997.
Ž. L. Jelić, M. V. Milošević and A. V. Silhanek, “Velocimetry of superconducting vortices based on stroboscopic resonances,” Scientific Reports, vol. 6, October 2016.
Z.-C. Wang, J. D. Rogers, X. Yao, R. Nichols, K. Atay, B. Xu, J. Franklin, I. Sochnikov, P. J. Ryan, D. Haskel and F. Tafti, “Colossal Magnetoresistance without Mixed Valence in a Layered Phosphide Crystal,” Advanced Materials, vol. 33, p. 2005755, 2021.
Aull, S., O. Kugeler, and J. Knobloch. “Trapped magnetic flux in superconducting niobium samples.” Physical Review Special Topics-Accelerators and Beams 15, no. 6 (2012): 062001.
Aull, S., J. Knobloch, and O. Kugeler. “Study of trapped magnetic flux in superconducting niobium samples.” In Proc. 15th Int. Conf. on RF Superconductivity, pp. 702-706. 2011.
Gonnella, Dan, John Kaufman, and Matthias Liepe. “Impact of nitrogen doping of niobium superconducting cavities on the sensitivity of surface resistance to trapped magnetic flux.” Journal of Applied Physics 119, no. 7 (2016).
Jeon, Kun-Rok, Chiara Ciccarelli, Hidekazu Kurebayashi, Lesley F. Cohen, Xavier Montiel, Matthias Eschrig, Thomas Wagner et al. “Effect of meissner screening and trapped magnetic flux on magnetization dynamics in thick Nb/Ni 80 Fe 20/Nb trilayers.” Physical Review Applied 11, no. 1 (2019): 014061.
Tomkow, Lukasz, Anis Smara, Vicente Climente-Alarcon, and Bartek A. Glowacki. “Distribution of trapped magnetic flux in superconducting stacks magnetised by angled field.” Journal of Superconductivity and Novel Magnetism 33 (2020): 1299-1305.
Liarte, Danilo B., Daniel Hall, Peter N. Koufalis, Akira Miyazaki, Alen Senanian, Matthias Liepe, and James P. Sethna. “Vortex dynamics and losses due to pinning: Dissipation from trapped magnetic flux in resonant superconducting radio-frequency cavities.” Physical Review Applied 10, no. 5 (2018): 054057.
Lousberg, Gregory P., Marcel Ausloos, Ph Vanderbemden, and Benoît Vanderheyden. “Bulk high-Tc superconductors with drilled holes: how to arrange the holes to maximize the trapped magnetic flux?.” Superconductor Science and Technology 21, no. 2 (2008): 025010.
Watanabe, Norimichi, Akiyoshi Nakayama, and Susumu Abe. “Influence of trapped magnetic flux quantum on two-dimensional magnetic field dependence of a Josephson junction.” Journal of applied physics 101, no. 9 (2007).
Zhu, B. Y., F. Marchesoni, and Franco Nori. “Controlling the motion of magnetic flux quanta.” Physical review letters 92, no. 18 (2004): 180602.
Kuzmin, Yu I. “Dynamics of the magnetic flux trapped in fractal clusters of normal phase in a superconductor.” Physical Review B 64, no. 9 (2001): 094519.
Mannhart, J., J. Bosch, R. Gross, and R. P. Huebener. “Two-dimensional imaging of trapped magnetic flux quanta in Josephson tunnel junctions.” Physical Review B 35, no. 10 (1987): 5267.
Balachandran, Shreyas, Anatolii Polyanskii, Santosh Chetri, Pashupati Dhakal, Yi-Feng Su, Zu-Hawn Sung, and Peter J. Lee. “Direct evidence of microstructure dependence of magnetic flux trapping in niobium.” Scientific reports 11, no. 1 (2021): 5364.
Parajuli, Ishwari Prasad, Gianluigi Ciovati, and Jean R. Delayen. “Magnetic field sensors for detection of trapped flux in superconducting radio frequency cavities.” Review of Scientific Instruments 92, no. 10 (2021).
Uchida, N., K. Enpuku, Y. Matsugaki, S. Tomita, F. Irie, and K. Yoshida. “Flux trapping in Josephson tunnel junctions.” Journal of applied physics 54, no. 9 (1983): 5287-5292.
Nappi, C., R. Cristiano, and M. P. Lisitskii. “Fiske steps in annular Josephson junctions with trapped flux quanta.” Physical Review B 58, no. 17 (1998): 11685.
Vernik, I. V., S. Keil, N. Thyssen, T. Doderer, A. V. Ustinov, H. Kohlstedt, and R. P. Huebener. “Fluxon pinning in annular Josephson junctions by an external magnetic field.” Journal of applied physics 81, no. 3 (1997): 1335-1340.
Tarte, E. J., H. W. Lean, and J. R. Waldram. “The effect of trapped flux upon the magnetic field dependence of the critical current of Josephson junctions.” IEEE Transactions on Applied Superconductivity 5, no. 2 (1995): 2388-2391.
Jackman, Kyle, and Coenrad J. Fourie. “Flux trapping experiments to verify simulation models.” Superconductor Science and Technology 33, no. 10 (2020): 105001.
Nakayama, Akiyoshi, Yohei Nishi, Norimichi Watanabe, Susumu Abe, and Yoichi Okabe. “Measurement of trapped flux magnetic field near the superconducting film by the dependence of superconducting current through a Josephson junction sensor.” In Journal of Physics: Conference Series, vol. 234, no. 4, p. 042023. IOP Publishing, 2010.
Fedorov, Kirill G., Anastasia V. Shcherbakova, Roland Schäfer, and Alexey V. Ustinov. “Josephson vortex coupled to a flux qubit.” Applied Physics Letters 102, no. 13 (2013).
Aaroe, M., R. Monaco, R. Rivers, V. Koshelets, and Jesper Mygind. “Quench-induced trapping of magnetic flux in annular Josephson junctions.” In Journal of Physics: Conference Series, vol. 97, no. 1, p. 012279. IOP Publishing, 2008.

Despite years of intensive research, flux trapping in superconducting integrated circuits remains an omnipresent detractor of reliable circuit operation affecting different types of superconducting circuits, from quantum to classical, from analog to digital, fabricated using variety of processes and material choices. The difficulty stems from the fact that the probability of flux trapping depends on a large set of parameters including specific circuit designs, moat structures, local magnetic field configuration in proximity of the chip, fabrication lots, materials, magnetic shielding quality, test setups, etc. Furthermore, the exact correlation between specific flux trapping pattern and circuit failure mode is also challenging. To date, flux trapping remains a serious impediment for scaling of superconducting electronics (SCE) to large practical systems.

Typically, the focus of prior approaches has been directed to various mitigation strategies for dealing with trapped flux from circuit design to cryopackage engineering—none of them capable of solving the problem entirely. Moreover, these methods are not particularly scalable or effective, as they come at the expense of either circuit density, overall complexity, limiting architectural choices, or requiring more expensive and sophisticated magnetic shielding. Even with excellent magnetic shielding, with six orders of magnitude or more of magnetic field attenuation (a shielding factor of>10⁶), some flux remains when a superconducting electronic (SCE) integrated circuit (IC) is cooled to below the transition temperature. This flux is frozen in as trapped fluxons in the form of Abrikosov or Pearl vortices that affect SCE circuit operation. Practical shields are far less efficient with a typical shielding factor of about 10⁴. Traditional mitigation methods utilize moats in superconducting ground planes to “attract” vortices and rely on time-consuming, repeated SCE chip thermal cycling above the critical temperature in order to reposition trapped flux to a more benign pattern.

Multiple studies have examined the optimal sizing and placement of moats to trap flux, fewer ones considered the effects of moat-captured fluxons on circuit operation. As integration density increases, extensive networks of moats are becoming too area-expensive and not scalable. As moats are squeezed to be smaller with higher integration density, the critical field at which they are still likely to trap flux, and thus the uncertainty about where flux pinning will likely occur, increases.

Superconductors are known to exclude magnetic fields from their interior, except for type II superconductors, which allow the entry of magnetic fields in the form of vortices. en.wikipedia.org/wiki/Type-II_superconductor. These vortices, also referred to as fluxoids, consist of both magnetic fluxes induced by external magnetic fields and circulating supercurrents. Owing to the single-valued nature of the superconducting order parameter, the fluxoid follows quantization. The quantized value of the fluxoid (Φ_{F}) is determined by the sum of the magnetic flux (Φ_{B}) and the supercurrent flux (Φ_{J}), expressed as Φ_{F}=Φ_{B}+Φ_{J}=Φ₀, where Φ₀=h/2e, with h and e being Plank's constant and the electron charge, respectively. When the contribution of the supercurrent is negligible (Φ_{J}=0), the quantization of the fluxoid is reduced to the quantization of the magnetic field flux (Φ_{F}=Φ_{B}=Φ₀). Conversely, in the presence of significant supercurrents, the quantized entity becomes the fluxoid rather than the magnetic field flux. Kim, G., Yun, J., Yang, J. et al. Vortex confinement through an unquantized magnetic flux. NPG Asia Mater 16, 44 (2024). doi.org/10.1038/s41427-024-00564-6.

For continued scaling of integrated superconducting circuits to millions of Josephson junctions and more, a new approach is needed.

### SUMMARY OF THE INVENTION

In contrast to the prior art, the present technology provides a radical approach leading to a complete solution of this problem, by moving the trapped flux out of the active circuit areas, instead of traditional attempts to find better mitigation strategies. The present technology is highly scalable, and results in available increase in circuit integration density, easing routing constraints, substantial simplification of magnetic shielding, and increasing the overall reliability and stability of SCE circuit operation. The technique does not require an extensive networks of moats, repetitive thermal cycling of the entire chip or cryopackage, cumbersome shielding or active magnetic shielding.

The technology is based on active steering or sweeping of vortices around a chip using a specially designed network of control lines which produce both local heating and local magnetic gradients in the superconducting circuits of interest. These control lines are placed in close proximity to the circuits, so that small electrical currents may have a large effect in producing both substantial local heating and substantial magnetic forces on the trapped vortices. The close proximity also permits achieving relatively large spatial gradients near the trapped flux.

The heating is balanced by the cooling from a cryogen or cryocooler. The circuit may therefore include at least one of a thermal sensing structure, a magnetic field sensing structure (e.g., a SQUID), and a critical current sensing structure, to permit optimization of the localized heating (and/or magnetic field), by limiting the energy consumption, and latency of return to the normal operating temperature, due to unnecessary (excess) heating of the structure. Similarly, a sensor permits the control line to be driven sufficiently to achieve an effective state. This feedback-based optimization prevents unnecessary cooling, while ensuring efficacy. The feedback processing may be performed on-chip (i.e., within the same integrated circuit), on a different chip (e.g., a superconducting circuit) within the same cryogenic environment, or on an external circuit (e.g., a room temperature circuit).

The sensing may be functional, i.e., Josephson junction constructed and biased so as to be responsive to temperature changes and magnetic fields around the unpinning temperature or critical temperature. A set of sensors may be provided, having an incremental optimal sensing value or threshold, to permit narrow bracketing of the effect.

This combination of heat and magnetic gradients act to sweep the magnetic vortices away from the superconducting circuits of interest. This magnetic flux may be diverted to a region of the chip (a “flux dump”) where they will have negligible effect on the circuits, or alternatively eliminated from the chip entirely. In this way, superconducting integrated circuits with up to millions of Josephson junctions can be prepared, which contain no external flux quanta.

For example, for a 1 cm² circuit, this corresponds to an effective magnetic field less than 20 pT. For comparison, the earth's magnetic field is about 50 μT, two million times larger. This is beyond what can be achieved using conventional magnetic shielding techniques.

FIGS. 1A-1D illustrate several preferred embodiments of configurations for the control lines relative to the superconducting circuits.

FIG. 1A shows a cross-sectional view of an array of control lines (labeled HS) on the same substrate as the superconducting circuits (labeled SFQ cct, for single-flux-quantum circuit), separated only by a thin insulator layer (“dielectric”).

FIG. 1B shows the control lines on the reverse side of the substrate (typically silicon) from the superconducting circuits.

FIG. 1C shows the control lines on a separate chip (“ClearFlux”) which is flip-chip bonded onto the chip with the superconducting circuits. Flip-chip bonding of superconducting ICs is well known in the prior art. See, for example, U.S. Pat. No. 11,711,985, “System and method for superconducting multi-chip module”, included herein by reference.

FIG. 1D shows a top view of the configuration of FIG. 1A, with a portion of a superconducting IC shown.

The array control lines may be evenly spaced across the chip, but periodic spacing is not required. Control lines are provided close to the center of the chip, close to the edge of the chip, and in intermediate regions between the center and the edge. The flux sweeping process comprises moving trapped flux from the center toward the edges of the chip.

In one embodiment, the control lines may comprise metallic thin films that are resistive (i.e., not superconducting) at the operating temperature of the circuit. A current I passing through such a line will produce both local Joule heating and also a circumferential magnetic field surrounding the line. The Joule heating will raise the temperature of the nearby superconducting circuits, for example from 4 K to a temperature˜8-9 K, still less than the critical temperature T_{c}=9.2 K for niobium. This will substantially reduce the pinning force required to move a trapped vortex. In this way, a current I˜1 mA in a control line is expected to easily move a trapped fluxon in a circuit near the line.

The circumferential magnetic field is given by B=μ₀I/2πr, where r is the distance from the center of the line, and μ₀=1.26 μH/m is the permeability of free space. This magnetic field will exert a transverse force (sometimes known as the Lorentz force) on a trapped vortex, moving it in a transverse direction given by the vector product I×Φ₀, where Φ₀ points either up or down, and I points in the direction of current flow. This is illustrated in FIG. 2, which distinguishes a vortex (pointing into the page) from an “anti-vortex” pointing out of the page. The current directions for moving the anti-vortex are reversed.

FIG. 3 represents a conceptual picture of one embodiment of sequential steps in the Flux-Sweeping process for the configuration of FIG. 1A. Assume that Φ₀ points up for the trapped vortices, the currents on the left point out of the page, and the currents on the right point into the page. In the first time-step (labeled T1), the currents in the central heater lines (H1) are turned on, generating spreading heat indicated by the radial arrows. This will force the vortices under these lines to move outward, as indicated by the red arrows in the section labeled “SFQ Circuit”. In the next time-step T2, the heater currents in H1 are maintained, and the currents in H2 are turned on. This will force the vortices to move further outward. In time-steps T3 and T4, currents in H3 and H4 are turned on, forcing the vortices to move further outward, while H1 and H2 lines can be turned off. At the end of the process, the vortices have crossed the superconducting ground plane (a superconducting film with no Josephson junctions), and are trapped in the “flux dumps” at the outer margins.

These flux dumps may comprise holes in the superconducting ground plane, or another structure designed to attract vortices. When all control currents are turned off and the superconducting films cool down (to ˜4 K), the spontaneous screening supercurrents in the ground plane should prevent the vortices from re-entering the region of the superconducting circuits. The superconducting integrated circuits can then be operated without interference from the magnetic flux.

The flux sweeping effect may also be used to intentionally create, maintain, and alter magnetic fields in certain regions of a superconducting device. For example, the trapped flux can activate, deactivate, or modulate regions of an integrated circuit, allowing fine control over circuit operation, especially in analog domains, while preserving the trapped currents. This can be implemented, for example, to require less energy to sweep a trapped flux around a device than to inject and remove the currents themselves. Further, given that the trapped flux currents themselves may be large, the sweeping system may operate faster than using quantum logic to change the magnetic field. The trapped flux may also assist in calibrating the operation of a circuit. For example, a circuit may be provided on one portion of a circuit to create and adjust the strength of a trapped magnetic flux, which may then be swept to an operational portion of the device that operates dependent on the strength of a trapped magnetic flux. In another embodiment, the trapped flux serves as an energy storage system, and the trapped flux may be swept to a coupler to replenish or employ the stored energy. Therefore, the flux sweeping technology is not limited to use in applications where the trapped flux is universally undesirable, and may be exploited within the operation of the device.

It is advantageous that both the heat and the magnetic field are present at the same time in the same location in the circuit. Without the heat, the pinning force would be too large to ensure effective sweeping of all vortices, and therefore the trapped flux is maintained in its location. After the vortices have been swept away, the control current can be turned off, cooling the superconducting devices, and trapping the vortices in an alternative location sufficiently far from the devices. While the heating and magnetic fields from the control lines may be correlated, in other cases, a magnetic field may be controlled by superconducting elements, which do not have associated Joule heating. The heating may be performed with a twisted (magnetic field cancelling) pair of control lines (which may be formed lithographically on the surface of the integrated circuit). Therefore, the heating and magnetic field imposition can be independent controlled, or at least partially separately controlled. This, in turn, facilitates multiplexing of control signals.

The magnitudes and time-sequences of the control currents can be guided by accurate modeling of the flux trapping and de-trapping processes close to the transition temperature, local heating in multilayer ICs with temperature fluctuations and the effects of thermal gradients.

Verification of the flux sweeping can be performed using special SQUID monitors of magnetic fields, embedded in the IC, which can also monitor the local heating.

The control lines for heat generation may comprise resistive metallic thin films with resistance per square that is preferably of order 1 ohm. These lines may be of order 1 μm wide. Heater currents may comprise a DC current of either polarity, or AC current at high frequency (for example in the GHz range), or any appropriate pulse sequence. For magnetic field generation, of course, the current polarity is critical; reversing the direction of the current reverses the transverse direction of flux flow. Magnetic generation lines and heater lines may be separately optimized, and may be interleaved. For example, a superconducting control line can generate a large magnetic field without heat generation. In one preferred embodiment, magnetic generation lines may comprise superconducting niobium or niobium nitride, while heater lines may comprise a resistive non-superconducting alloy or compound such as Ti—Pd or MoN.

Control currents for heater and magnetic generation lines may be generated externally under program control. Flux sweeps may be repeated multiple times for best performance. A single flux sweep may be quite fast, on the order of microseconds. Complete cooldown to the operating temperature (typically ˜4 K) may take somewhat longer, but additional flux sweeps need not wait for full cooldown. The circuit may be optimized to operate at a temperature above complete cooldown. Throughout the process, care should be taken to avoid unintended reverse flux flow from flux dumps back toward the superconducting circuit, and to avoid vortex generation from control currents. In one preferred embodiment, sensor signals from embedded SQUIDs can provide feedback signals to enable automated closed-loop control of the defluxing process.

It is an object to provide a system to sweep trapped magnetic flux from a superconducting integrated circuit on a chip operating at a cryogenic operating temperature, comprising: a superconducting integrated circuit, comprising a plurality of superconducting devices, and at least one structure subject to magnetic flux trapping; and a plurality of control lines configured to produce a timed sequence of control current pulses which generate magnetic fields and alter an operating margin of the at least one structure subject to magnetic flux trapping with respect to a critical state; the sequence of control current pulses being adapted to locally sweep magnetic flux trapped in the at least one structure, by reduction of an affinity of the trapped magnetic flux for at least one structure by reducing the margin, and supply of a magnetic field to induce the trapped magnetic flux to relocate.

It is also an object to provide a method for sweeping trapped flux from a chip comprising a superconducting integrated circuit, comprising: operating the superconducting integrated circuit at a cryogenic temperature; and applying at least one first current pulse adapted to heat a first region of the superconducting integrated circuit close to a superconducting critical temperature to weaken a binding of magnetic flux to the first region, and to concurrently generate a magnetic field gradient in the first region sufficient to sweep the magnetic flux having the weakened binding.

It is a further object to provide a method for sweeping a trapped vortex from a chip comprising a superconducting integrated circuit, comprising: operating the superconducting integrated circuit at a cryogenic temperature; and applying at least one current pulse adapted to heat a region of the superconducting integrated circuit close to a superconducting critical temperature, to thereby weaken a binding of trapped vortex to the region, and to concurrently generate a magnetic field gradient in the region sufficient to sweep the trapped vortex having the weakened binding from the region. The method may further comprise receiving feedback from at least one superconducting quantum interference device (SQUID) sensor, to track a progress of sweeping of the trapped vortex, wherein the superconducting integrated circuit is associated with a plurality of control lines configured to produce a timed sequence of a plurality of current pulses which generate magnetic field gradients and alter an operating margin of at least one structure in the region subject to vortex trapping with respect to a critical state, said applying comprising sequencing the plurality of current pulses to locally sweep the trapped vortex in the at least one structure, by reduction of an affinity of the trapped vortex for the at least one structure by reducing the margin, and supplying the magnetic field gradients to induce the trapped vortex to relocate toward at least one of a periphery of the superconducting integrated circuit, and a flux dump, configured to maintain the swept vortex away from the at least one structure, dependent on the feedback from the at least one superconducting quantum interference device (SQUID) sensor.

It is a still further object to provide a superconducting circuit system, comprising: an integrated circuit comprising a plurality of superconducting devices, and at least one structure configured to trap a vortex; a plurality of control lines configured to produce heat and magnetic fields which alter a pinning of the trapped vortex in the at least one structure and induce a Lorenz force to relocate the trapped vortex; and a control configured to generate a timed sequence of control current pulses in plurality of the control lines, adapted to reduce a pinning of the trapped vortex to the at least one structure and sweep the trapped vortex away from the at least one structure using the induced Lorenz force.

The control lines may be deposited over the superconducting integrated circuit, or on a side of the chip opposite the superconducting integrated circuit, or on a separate chip from the chip with the superconducting integrated circuit, wherein the separate chip is mounted on the chip with the superconducting integrated circuit using a flip-chip bonding configuration.

The sequence of control current pulses may be applied first to control lines in a center portion of the superconducting integrated circuit, and are successively applied to a peripheral region of the superconducting integrated circuit to move outward towards an edge of the superconducting integrated circuit.

The control lines may lie above the superconducting integrated circuit, on the chip, and/or on a reverse side of the chip and/or on a separate chip from the superconducting integrated circuit, wherein the separate chip is mounted on the superconducting integrated circuit using a flip-chip bonding configuration.

The control lines may be present near a center portion of the superconducting integrated circuit, the outer edge of the superconducting integrated circuit, and regions in between.

The sequence of control current pulses may be applied first to control lines in the center portion of the superconducting integrated circuit, and the sequence successively moves outward towards the edge of the superconducting integrated circuit.

The control current pulses may be configured to reduce the margin by local heating of the superconducting devices to a temperature close to, but not exceeding, a critical temperature of the superconducting devices.

The control pulses may be further configured to supply the magnetic field to produce a magnetic force on the trapped magnetic flux, sufficient to move the trapped magnetic flux away from the superconducting devices.

The control current pulses may be adapted to remove trapped magnetic flux from the superconducting devices by expulsion from the chip.

The control current pulses may be adapted to remove the trapped magnetic flux from the superconducting devices by transfer to one or more magnetic flux dumps located away from the superconducting devices.

The control lines may comprise resistive metallic thin films optimized for heat generation. The control lines may be configured to generate heat on the superconducting integrated circuit by Joule heating. The control lines comprise at least one of Titanium-Palladium and Molybdenum Nitride.

A control circuit may be provided, configured to generate the sequence of control pulses. The sequence of control pulses may have a predefined sequence. The control circuit may be configured to generate a plurality of the predefined sequences in succession.

The control lines may comprise superconducting thin films optimized for generation of magnetic fields. The control lines may be formed of niobium, niobium nitride, or aluminum (specially for quantum computing applications).

The at least one structure subject to magnetic flux trapping may be subject to an external magnetic field (such as the earth's magnetic field, an artificial magnetic field, or a magnetic field due to operation in an environment including varying electric currents), and the sequence of control current pulses may be adapted to reduce an effective magnetic field in the at least one structure subject by at least three orders of magnitude, such as three orders, four orders, five orders, six orders, or more. In some embodiments, a reduction of the field to zero is not a goal, and rather a non-zero field may be sought. For example, a precise field strength or quantized vortex may be an optimum operating state. Therefore, the system and process seeks to achieve the predetermined state, which may be zero or some other magnetic field, or vortex state.

The superconducting devices may comprise superconducting qubits, or single-flux-quantum logic circuits, or Josephson junction circuits.

The superconducting integrated circuit may comprise at least 100,000 Josephson junctions or at least 1 million Josephson junctions.

The superconducting devices may comprise superconducting sensors responsive to at least one of temperature and magnetic field.

The superconducting devices may comprise single-flux-quantum logic circuits.

The superconducting devices may comprise superconducting sensors, and/or superconducting quantum interference device sensors, and/or superconducting quantum interference filter sensors. The superconducting devices may comprise superconducting sensors responsive to at least one of temperature and magnetic field.

The system may further comprise a plurality of superconducting quantum interference device (SQUID) sensors configured to at least one of detect trapped magnetic flux and monitor a sweeping of the magnetic flux.

The system may further comprise a plurality of superconducting quantum interference device (SQUID) sensors configured to monitor a sweeping of the magnetic flux, comprising a magnetic field strength and a temperature.

The control current pulses may be applied under feedback control based on the superconducting quantum interference device (SQUID) sensors.

The sequence of control current pulses may comprises at least one pulse having an intensity or duration which varies in dependence on a quantity of the trapped flux.

The system may further comprise a control circuit configured to generate the control current pulses.

The system may further comprise a control circuit, a plurality of sets of independently operable control lines, and at least one magnetic field sensor associated with each set of control lines, each set of control lines being disposed on a respective portion of the chip is operated by the control circuit dependent on the associated at least one magnetic field sensor.

The control circuit may be located on the chip, in the superconducting integrated circuit, or in an integrated circuit adjacent to the superconducting integrated circuit.

The control circuit may be implemented in logic that operates at room temperature.

The control circuit may be feedback dependent.

The sequence of control current pulses may be applied multiple times in sequence to successively reduce the trapped flux.

The magnetic flux may be swept to a periphery of the superconducting integrated circuit.

The at least one first current pulse may comprise a plurality of pulses, adapted to sequentially sweep the magnetic flux toward a periphery of the superconducting integrated circuit.

The method may further comprise sweeping the magnetic flux to at least one flux dump configured to trap magnetic flux away from the superconducting devices on the superconducting integrated circuit.

The method may further comprise receiving feedback from at least one superconducting quantum interference device (SQUID) sensor, to track a progress of magnetic flux sweeping.

The superconducting integrated circuit may be associated with a plurality of control lines configured to produce a timed sequence of control current pulses which generate magnetic fields and alter an operating margin of at least one structure subject to magnetic flux trapping with respect to a critical state.

The applying may comprise sequencing the control current pulses to locally sweep magnetic flux trapped in the at least one structure, by reduction of an affinity of the trapped magnetic flux for at least one structure by reducing the margin, and supplying a magnetic field to induce the trapped magnetic flux to relocate.

The method may further comprise receiving feedback from at least one superconducting quantum interference device (SQUID) sensor, to track a progress of magnetic flux sweeping, wherein the superconducting integrated circuit is associated with a plurality of control lines configured to produce a timed sequence of the plurality of pulses which generate magnetic fields and alter an operating margin of at least one structure subject to magnetic flux trapping with respect to a critical state, said applying comprising sequencing the control current pulses to locally sweep magnetic flux trapped in the at least one structure, by reduction of an affinity of the trapped magnetic flux for at least one structure by reducing the margin, and supplying a magnetic field to induce the trapped magnetic flux to relocate toward at least one of a periphery of the superconducting integrated circuit, and a flux dump configured to trap magnetic flux away from the superconducting devices on the superconducting integrated circuit, dependent on the at least one superconducting quantum interference device (SQUID) sensor.

It is a further object to provide a superconducting circuit system, comprising: an integrated circuit comprising a plurality of superconducting devices, and at least one structure configured to trap magnetic flux; a plurality of control lines configured to produce heat and magnetic fields which alter a pinning of the trapped magnetic flux for the structure and induce a Lorenz force to relocate the magnetic flux; and a control configured to generate a timed sequence of control current pulses in the control lines, adapted to reduce a pinning of the magnetic field to the structure and sweep the trapped magnetic flux away from the structure using the induced Lorenz force.

### BRIEF DESCRIPTION OF THE DRAWINGS

FIGS. 1A-1D show a conceptual picture of several preferred embodiments of the flux-sweeper assembly.

FIG. 1A shows a cross-sectional view of control lines lying above the superconducting circuits.

FIG. 1B shows control lines on reverse side of superconducting IC chip.

FIG. 1C shows control lines on separate chip flip-chip bonded to superconducting IC chip.

FIG. 1D shows a top view of FIG. 1A with control lines above portion of superconducting IC.

FIG. 2 shows the relative orientations of the control current, vortex field, and transverse Lorentz force acting on a vortex or anti-vortex.

FIG. 3 shows a conceptual picture of the time-sequence of control currents in the configuration of FIG. 1A, configured to sweep magnetic vortices from the center of the superconducting IC.

FIG. 4 shows the cross-sectional view of FIG. 1A, mounted on a cryocooler.

FIG. 5A shows a top view of array of control lines over the superconducting chip, with current pulse sequence of FIG. 2 also shown.

FIG. 5B shows a top view of an alternative 2D configuration of control lines, which will sweep vortices to all four edges of chip.

FIGS. 6A-6E show several alternative designs of control lines, which may include separately designed lines for heat and magnetic field generation.

FIG. 7 shows a block diagram of a programmable 20-channel current source.

### DETAILED DESCRIPTION OF THE PREFERRED EMBODIMENTS

The technology may be used to remove trapped flux from the device area of a superconductor integrated circuit. This objective is achieved through flux-sweeping structures that combine thermal and magnetic gradients to lessen trapped flux pinning at a location, and sweep the trapped flux into flux dumps spaced across the die surface, or entirely out of an integrated circuit.

This process aims for a four-order-of-magnitude reduction in the required magnetic shielding to permit vortex-free operation of superconductor integrated circuits. Embodiments of the technology encompass the design, testing, and verification of on-chip or bonded-chip active flux management, through which pinned vortices can be migrated out of active circuit areas and/or collected into flux dumps, where coupling to superconductor electronic circuits on the chip is negligible. This goal is realized by integrating a specialized network of control lines comprising heating lines capable of generating local thermal and electromagnetic gradients to move trapped vortices while a superconductor circuit remains cooled below its critical temperature.

The design of current pulse sequences is guided by modeling vortex dynamics within multi-layer Nb and NbN superconducting films, which can be extendable to other superconducting materials. This performance can be verified with on-chip SQUID sensors. These SQUID sensors, also serving as sensitive on-chip temperature monitors, can track the density and movement of vortices on a chip before, during, and after flux sweeping in order to optimize the design of the heating network and thermal and magnetic gradient waveforms.

This solves the problem of flux trapping completely, contrasting with common methods of mitigating flux trapping through various moat-riddled layout designs and heavy shielding methods which compromise the circuit density and overall cryosystem complexity. The present technology provides a highly practical and scalable technique for removing trapped magnetic vortices in situ from active superconducting circuit areas. The scalable thermal and magnetic gradient vortex-control integrated circuitry enables reliable, predictable, and stable superconducting electronics (SCE) circuit operation irrespective of its type, design, and application. It also substantially simplifies the SCE cryogenic system by achieving a four-order-of-magnitude reduction in required magnetic shielding (from one million to ˜100), ensuring vortex-free operation of the electronics on a multi-layer superconductor integrated circuit. This improvement significantly reduces shielding infrastructure and moat real estate, thus freeing up chip space for higher integration density. The technology further increases the reliability of SCE operation, reducing SCE test time by eliminating the need for multiple time-consuming defluxing warm-ups with unpredictable results.

Another aspect comprises SQUID test structures for monitoring the on-chip vortex behavior, providing data on density and movement before, during, and after the application of flux management techniques and during the single flux quantum (SFQ) circuit operation. This ensures accurate model-to-hardware correlation in the precise environment and shielding conditions that SCE circuits are typically operating. The SQUID test structures and the thermal and magnetic sensors can be the same or different devices.

A preferred embodiment involves positioning the SQUIDs close to the edges of the flux dump moat to gauge the magnetic coupling effect of trapped fluxons on the SQUID loops. The SQUID is capable of measuring as little as a single fluxon, and as many as hundreds of fluxons in the flux dumps.

These monitoring SQUIDs can also be used for real-time temperature monitoring, to provide immediate and accurate feedback on the thermal environment within the superconducting films, because critical current I_{c} of the Josephson junctions in the SQUIDs are strongly temperature-dependent near T_{c}. By measuring the self-inductance of each SQUID, they can be employed for real-time temperature measurements. Furthermore, various SQUIDs, each with a distinct self-inductance, will be installed around the moats of each flux dump. This strategy of utilizing multiple SQUIDs with differing self-inductances enhances the precision of measuring temperature changes near T_{c}.

Various other temperature measurement techniques may also be used. For example, thermally sensitive Josephson junctions. See:
Zgirski, M., Marek Foltyn, Alexander Savin, K. Norowski, Matthias Meschke, and J. Pekola. “Nanosecond thermometry with Josephson junctions.” Physical Review Applied 10, no. 4 (2018): 044068.
Wang, L. B., O-P. Saira, and J. P. Pekola. “Fast thermometry with a proximity Josephson junction.” Applied Physics Letters 112, no. 1 (2018).
Soulen, R. J., W. E. Fogle, and J. H. Colwell. “Measurements of absolute temperature below 0.75 K using a Josephson-junction noise thermometer.” Journal of low temperature physics 94 (1994): 385-487.
Giazotto, Francesco, and María José Martínez-Pérez. “The Josephson heat interferometer.” Nature 492, no. 7429 (2012): 401-405.
Durandetto, Paolo, and Andrea Sosso. “Using a Josephson junction as an effective on-chip temperature sensor.” Superconductor Science and Technology 34, no. 4 (2021): 045008.
Martinoli, Piero, and Chris Leemann. “Two dimensional Josephson junction arrays.” Journal of Low Temperature Physics 118 (2000): 699-731.
Fox, Anna E., Evan B. Golden, Paul D. Dresselhaus, and Samuel P. Benz. “On-chip temperature distribution of Josephson voltage standard devices.” IEEE Transactions on Applied Superconductivity 27, no. 4 (2016): 1-5.

Appropriate calibration of the SQUIDs, (or other temperature sensor) for both magnetic field and temperature enables automated program control of the flux-sweeping control currents and the entire process, which may be repeated multiple times if needed.

The automated control may be self-contained within an integrated SCE IC, or controlled off chip, either by another chip within a cryostat, or by room temperature (RT) electronics located outside of the cryostat. In the case of on-chip control, the sensors, e.g., SQUIDs, are interfaced with a circuit that determines a local temperature or determines a relationship of the thermal conditions of a respective SQUID with respect to a threshold. A set of gates are configured to process the thermal measurement data, and control an initiation and sequence of flux sweeping process. On the other hand, in an off-chip embodiment, and especially using RT electronics, a computer software implemented process may be used, which generally favors higher computational complexity and more sophisticated models of SCE operation. However, information transfer out of the cryostat, or even within the cryostat, incurs various penalties.

In managing the trapped flux, it is typically desired to sweep the flux to flux traps (e.g., moats) on a periphery of the IC. However, it may also be possible to sweep the flux off the IC die, for example onto an adjacent die, which may be adjacent along an x or y axis in a plane of the IC, or along a z axis to an adjacent IC. In this latter case, the trapped flux may advantageously be swept outside the periphery of the active IC, but within an area of a larger flux-sweeping IC.

In some cases, a closed loop feedback system may operate to detect trapped flux and null it by specifically counteracting it. This does not directly remove the flux or its effects on the proximate circuits, and rather the counteracting/counterbalancing current and corresponding flux impose a force that reduces the stability of the trapped flux at its location, and will increase a tendency for the trapped flux to migrate in permitted paths to a location that is not subject or less subject to the opposing influence. Therefore, the control signals may include not only lines carrying current for Joule heating and/or magnetic field generation surrounding the line, but also current carrying loops. These loops may be in the plane of the SCE IC, or include a current flow along a z-axis, for example through solder bumps through adjacent ICs. Advantageously, the solder bumps may be non-superconducting, and therefore dissipative. This will act to reduce occurrence of trapped flux in the sweeping circuit itself.

In a typical case, when a sweeping operation is triggered, a predetermined sequence, which may be specific for a location on the SCE IC, is initiated, that includes specified lines, currents and durations. At the end of the cycle, the temperature and magnetic field may be measured, and a new cycle commenced dependent on the starting condition(s). The flux sweeping process may be localized and adaptive within regions of the SCE IC, which may allow minimum disruption of SCE operation. For example, a non-adaptive sweep may employ a relatively large thermal load to warm large portions of the SCE IC to 9° K., and sweep all trapped flux toward peripheral flux-tolerant structures distant from the sensitive SCE circuits near the center of the IC. On the other hand, if trapped flux is detected only on a small portion of the SCE IC, the sweeping operation may need only warm a path across the IC toward a peripheral moat, while leaving other portions of the IC which do not have trapped flux, or are unaffected by trapped flux, unperturbed or minimally perturbed. This, in turn, will permit cooling of the affected structures back to operational temperature sooner, and impose reduced thermal load on the cryocooler.

The currents required to drive the control lines may be generated by a superconducting amplifier. See, U.S. Pat. No. 5,936,458, US 2023/0363292, US 202/30359915, U.S. Pat. Nos. 11,804,275, 11,730,066, 11,533,032, 11,411,159, 10,491,178, 7,724,083, US 2008/0290938, US 2008/0048762, U.S. Pat. Nos. 6,917,216, and 6,486,756.

The initial and subsequent cycles need not be the same, and indeed, due to the localized Joule heating and thermal diffusion of the SCE IC, the subsequent cycle(s) will generally have a different heating current. On the other hand, because the starting state of the SCE may differ, having a single cycle intended to necessarily complete the sweeping may lead to requirement for an excess basic process, leading to increased latency before the temperature of the SCE drops to the normal operating state. Note that the thermal sensors on the SCE may be used not only to initiate and control the sweeping cycle, but also to indicate that the SCE is ready for normal operation.

In some cases, the sweeping cycle and consequent thermal effects are limited to a portion of the SCE IC, and indeed, where the SCE IC includes multiple redundant circuits (cores), processing operations on one portion of the SCE IC can proceed concurrently with sweeping of flux on other portions of the SCE IC. In this case, the SCE generally includes a multiplexor to distribute signals and tasks to different cores. Similarly, the SCE IC may have a plurality of different functions, all of which need not be interrupted when the sweeping process is initiated or ongoing on a portion of the SCE IC.

When this process is optimized, the conventional requirements for passive or active magnetic shielding may be significantly relaxed. The earth's magnetic field is ˜50 μT, and it is easy to reduce that to less than 1 μT with conventional passive magnetic shielding (such as mu-metal). That is still too high for operation of sensitive single-flux-quantum (SFQ) logic circuits, superconducting qubits, and superconducting sensors arrays (such as SQUIDs and superconducting micro-bolometers), but the present invention provides a method to reduce the effective magnetic field by up to 6 orders of magnitude, by sweeping away trapped magnetic flux in the active region of the superconducting integrated circuits.

In another embodiment, the flux sweeping process may be used to compensate for external fields. That is, the goal in this case is not to sweep flux so that the residual flux from the trapped vortices is zero, and rather to establish a normalized field on the SCE IC which compensates for aberrations. In this case, in the presence of an external or uncontrolled magnetic field, the flux may be swept to a particular moat and maintained at a controlled level to establish a desired field condition. In most cases, the desired field condition will be a net field of near zero. However, in the case of arrays of junctions, it may be desired to establish a varying magnetic field, such as a linearly varying field. The present technology allows control over local magnetic field and local temperature on the SCE IC, and relatively rapid changes in both while the SCE is operational. Therefore, the utility of the technology is not limited to removal of trapped flux.

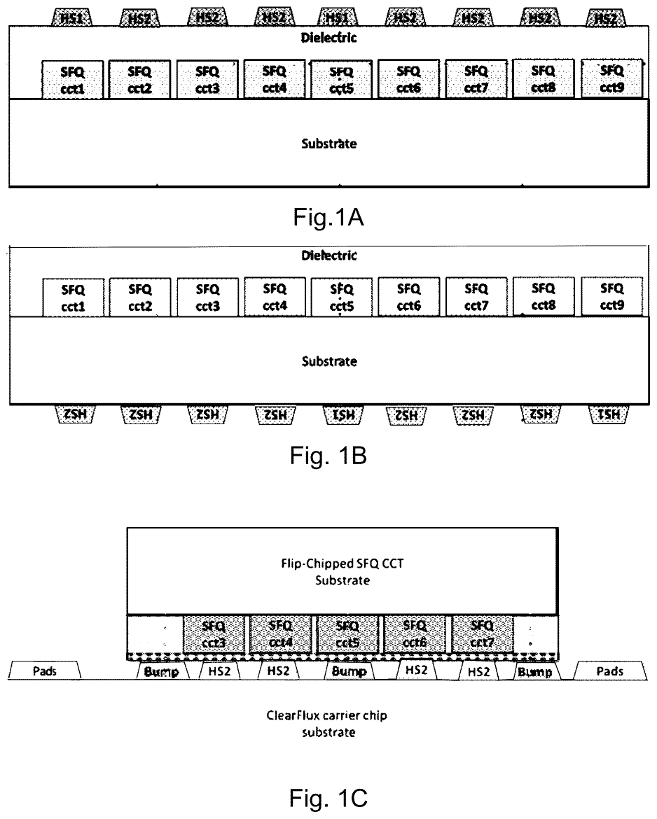

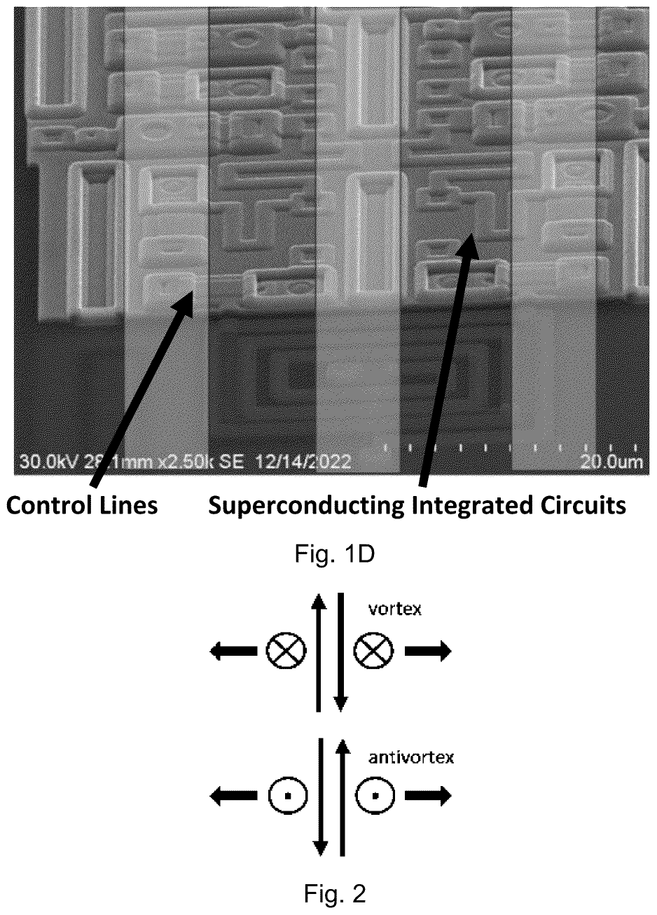

FIGS. 1A-1D show that there are several alternative configurations for integrated an array of current control lines close to superconducting circuits. In the approach of FIG. 1A and FIG. 1D, the control lines may be deposited directly on top of the superconducting circuits, with only a thin insulting layer (such as silicon dioxide) between them. Alternatively, in some cases, it may be preferable not risk damaging the superconducting IC, or to maintain optical access to the front of the IC. In that case, another approach, shown in FIG. 1B, is to place the control lines on the reverse side of the IC, but still close enough, thermally and magnetically, to enable full flux-sweeping from the IC. In other cases, it may be preferable to place the control current lines on a separate chip, wherein the control chip and the IC chip are mounted in a flip-chip geometry, as shown in FIG. 1C, with an array of solder bump bonds (as known in the prior art) holding the two chips together.

FIG. 2 shows the geometry of the transverse force on a magnetic vortex due to an electrical current. For a current pointing up (North) on the page and a vortex field pointing perpendicular into the page, the Lorentz force will push the vortex to the left. Reversing the direction of the current or the field (the “anti-vortex”) reverses the direction of the force. In most cases, the residual magnetic field will have a single direction reflecting the residual earth's magnetic field, but this method is general enough to account for either direction of flux, or even for inhomogeneous flux directions.

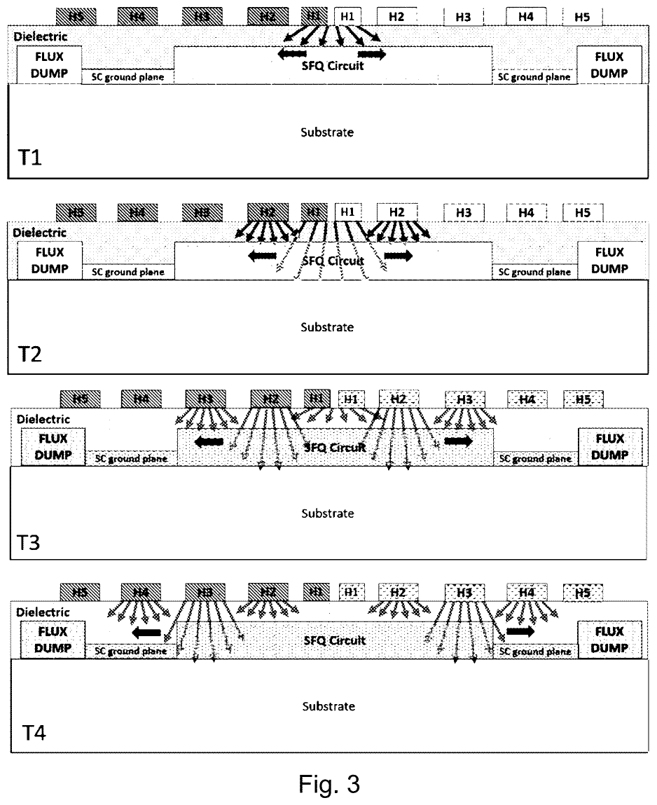

FIG. 3 presents the key steps in the process of flux-sweeping, with snapshots at sequential times T1, T2, T3, and T4. The process starts (T1) with currents in the center of the chip (the two lines labeled H1), which heats up the central region of the superconducting circuits to a temperature near Tc, and also applies a transverse Lorentz force on trapped vortices tending to make them move away from the center and toward both edges. If we assume here that the magnetic flux points up, then the left line H1 will have current pointing out of the page (pushing a vortex to the left), while the right line H1 will have the same current pointing into the page (pushing a vortex to the right). In the second time step shown (T2), the vortices have moved part-way toward the edge on both sides, and the next control currents (H2) are excited. They tend to push the vortices further out, as shown in the snapshot at time T3. By time T4, the vortices are under lines H4, beyond the functional superconducting circuits (labeled SFQ circuits here), and the central currents in H1 can be turned off, allowing that part of the chip to cool down. This is the region labeled “superconducting ground plane”, and once the vortices traverse this region (driven by currents in H5), they end up in the “flux dump” on the left and the right. After this, all the drive currents can be turned off, and the vortices will be trapped in the flux dumps, away from the active circuits.

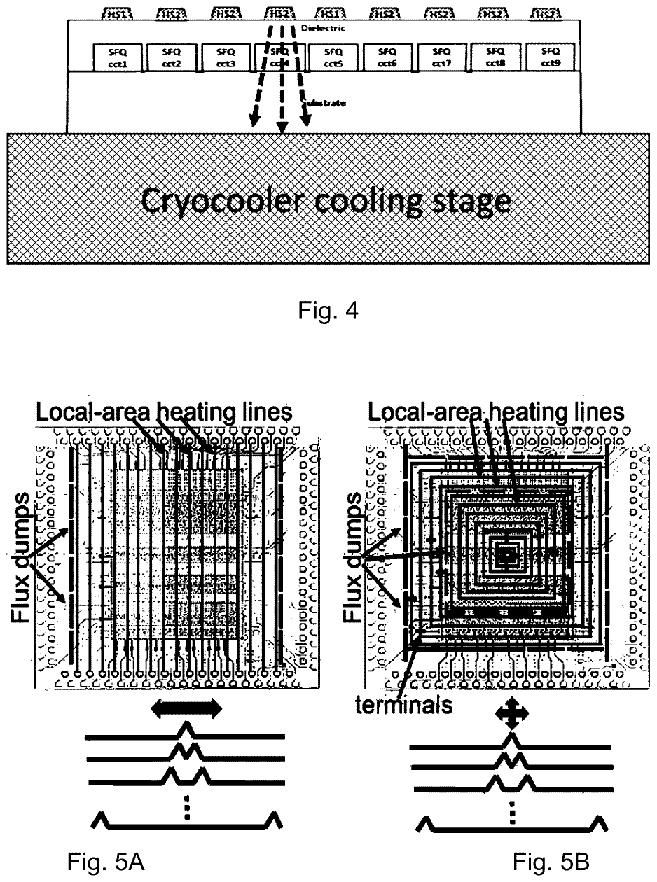

FIG. 4 addresses another issue, how is the heat from the control currents removed from the chip? In one embodiment, the chip may be immersed in liquid helium, but in another embodiment represented here, the chip is in a vacuum, and cooled by mounting on the cooling stage of a closed-cycle refrigerator, also known as a cryocooler. Given that the substrate is typically a single crystal of silicon, which is a good thermal conductor at cryogenic temperatures, the cryocooler keeps the substrate cooled to ˜4 K, which restricts the spreading of the local hotspot from the control current.

In some other applications such as quantum computing or certain sensor systems, the cryocooler may comprise a dilution refrigerator, cooling the superconducting circuit down to a temperature less than 1 K.

FIGS. 5A and 5B show the top view of two alternative configurations of control lines for a superconducting chip, typically several mm across, with electrical contacts around the edges. FIG. 5A shows a set of parallel control lines, consistent with FIG. 3, with a sequence of current pulses forcing trapped vortices to flux dumps on the left and right of the chip. FIG. 5B shows a set of 2D control lines, which tend to push vortices away from the center to flux dumps on the four sides of the chip.

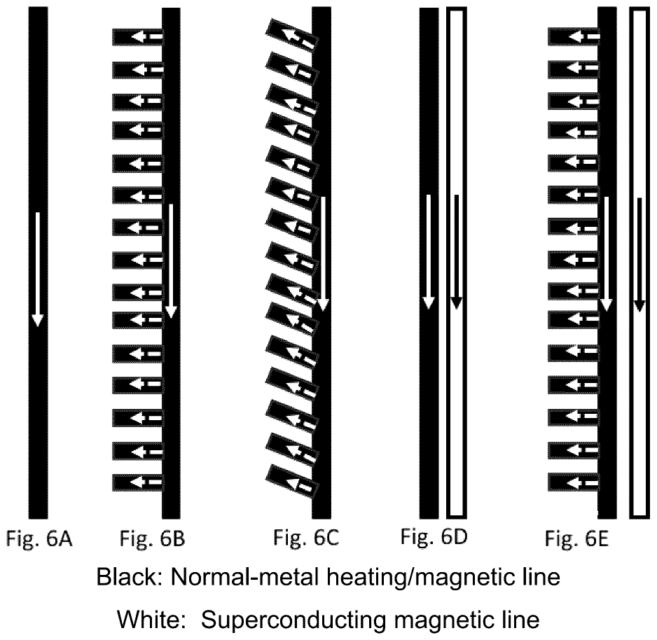

Finally, FIGS. 6A-6E show several designs for control lines for the flux sweeper. The black line in FIG. 6A represents the simple universal line described earlier, a normal (non-superconducting) line that generates both heat and magnetic fields. FIGS. 6B and 6C represent side tabs for more efficient heat-transfer. FIG. 6D represents two separately optimized lines, the black line for heating, and the white line for magnetic field generation. In this alternative, the field-generation lines can be superconducting, which then do not generate any heat. The heater lines can be driven by currents of any polarity, or AC currents, or sequences of fast pulses. FIG. 6E shows tabs as in FIGS. 6B and 6C, with represents two separately optimized lines, the black line for heating, and the white line for magnetic field generation, as in FIG. 6D. The heating line will also generate magnetic fields, but their effects may be negligible.

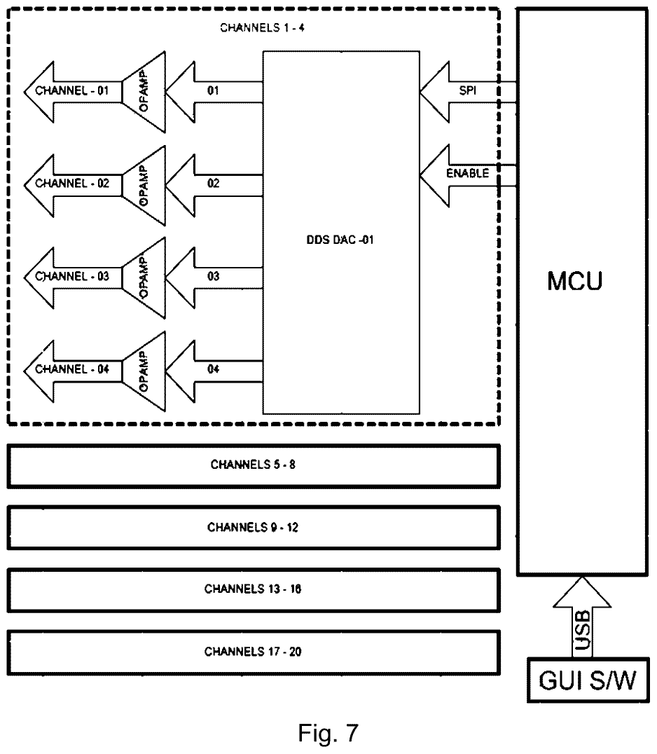

A separate programmable current source, as shown in FIG. 7 may be used to permit use of dedicating pads on the SCE IC to run flux-sweeping operation. This would release all standard chip pads for control of SFQ circuits and SQUID Sensors.

This disclosure has been described with reference to various specific embodiments and techniques. However, many variations and modifications are possible while remaining within the scope of the disclosure.

The claims of this document define certain combinations and subcombinations of elements, features and steps or operations, which are regarded as novel and non-obvious. Additional claims for other such combinations and subcombinations may be presented in this or a related document. These claims are intended to encompass within their scope all changes and modifications that are within the true spirit and scope of the subject matter described herein.

What is claimed is:

1. A system to sweep trapped magnetic flux from a superconducting integrated circuit on a chip operating at a cryogenic operating temperature, comprising:
a superconducting integrated circuit, comprising a plurality of superconducting devices, and at least one structure subject to magnetic flux trapping; and
a plurality of control lines configured to produce a timed sequence of control current pulses which generate magnetic fields and alter an operating margin of the at least one structure subject to magnetic flux trapping with respect to a critical state;
the sequence of control current pulses being adapted to locally sweep magnetic flux trapped in the at least one structure, by reduction of an affinity of the trapped magnetic flux for at least one structure by reducing the margin, and supply of a magnetic field to induce the trapped magnetic flux to relocate.

2. The system of claim 1, wherein the control lines are deposited over the superconducting integrated circuit.

3. The system of claim 1, wherein the control lines are deposited on a side of the chip opposite the superconducting integrated circuit.

4. The system of claim 1, wherein the control lines are deposited on a separate chip from the chip with the superconducting integrated circuit, wherein the separate chip is mounted on the chip with the superconducting integrated circuit using a flip-chip bonding configuration.

5. The system of claim 1, wherein the sequence of control current pulses is applied first to control lines in a center portion of the superconducting integrated circuit, and are successively applied to a peripheral region of the superconducting integrated circuit to move outward towards an edge of the superconducting integrated circuit.

6. The system of claim 1, wherein the control current pulses are configured to reduce the margin by local heating of the superconducting devices to a temperature close to, but not exceeding, a critical temperature of the superconducting devices.

7. The system of claim 6, wherein the control pulses are further configured to supply the magnetic field to produce a magnetic force on the trapped magnetic flux, sufficient to move the trapped magnetic flux away from the superconducting devices.

8. The system of claim 1, wherein the control current pulses are adapted to remove the trapped magnetic flux from the superconducting devices by transfer to one or more magnetic flux dumps located away from the superconducting devices.

9. The system of claim 1, further comprising a control circuit configured to generate the sequence of control pulses, wherein the sequence of control pulses has a predefined sequence, and the control circuit is configured to generate a plurality of the predefined sequences in succession.

10. The system of claim 1, wherein the control lines comprise resistive metallic thin films optimized for heat generation, and are configured to generate heat on the superconducting integrated circuit by Joule heating.

11. The system of claim 10, wherein the control lines comprise at least one of Titanium-Palladium and Molybdenum Nitride.

12. The system of claim 1, wherein the control lines comprise superconducting thin films optimized for generation of magnetic fields.

13. The system of claim 12, wherein the control lines comprise at least one of Niobium, Niobium Nitride, and Aluminum.

14. The system according to claim 1, wherein the at least one structure subject to magnetic flux trapping is subject to an external magnetic field, and the sequence of control current pulses is adapted to reduce an effective magnetic field in the at least one structure subject by at least three orders of magnitude.

15. The system of claim 1, wherein the superconducting devices comprise superconducting qubits.

16. The system of claim 1, wherein the superconducting devices comprise single-flux-quantum logic circuits.

17. The system of claim 1, wherein the superconducting devices comprise superconducting sensors responsive to at least one of temperature and magnetic field.

18. The system of claim 1, further comprising a plurality of superconducting quantum interference device (SQUID) sensors configured to at least one of detect trapped magnetic flux and monitor a sweeping of the magnetic flux.

19. The system of claim 1, further comprising a control circuit configured to generate the control current pulses.

20. The system of claim 1, wherein the sequence of control current pulses comprises at least one pulse having an intensity or duration which varies in dependence on a quantity of the trapped flux.

21. The system of claim 1, further comprising a control circuit, a plurality of sets of independently operable control lines, and at least one magnetic field sensor associated with each set of control lines, each set of control lines being disposed on a respective portion of the chip is operated by the control circuit dependent on the associated at least one magnetic field sensor.

22. A method for sweeping a trapped vortex from a chip comprising a superconducting integrated circuit, comprising:
operating the superconducting integrated circuit at a cryogenic temperature; and
applying at least one current pulse adapted to heat a region of the superconducting integrated circuit close to a superconducting critical temperature, to thereby weaken a binding of trapped vortex to the region, and to concurrently generate a magnetic field gradient in the region sufficient to sweep the trapped vortex having the weakened binding from the region.

23. The method of claim 22, further comprising:
receiving feedback from at least one superconducting quantum interference device (SQUID) sensor, to track a progress of sweeping of the trapped vortex,
wherein the superconducting integrated circuit is associated with a plurality of control lines configured to produce a timed sequence of a plurality of current pulses which generate magnetic field gradients and alter an operating margin of at least one structure in the region subject to vortex trapping with respect to a critical state,
said applying comprising sequencing the plurality of current pulses to locally sweep the trapped vortex in the at least one structure, by reduction of an affinity of the trapped vortex for the at least one structure by reducing the margin, and supplying the magnetic field gradients to induce the trapped vortex to relocate toward at least one of a periphery of the superconducting integrated circuit, and a flux dump, configured to maintain the swept vortex away from the at least one structure, dependent on the feedback from the at least one superconducting quantum interference device (SQUID) sensor.

24. A superconducting circuit system, comprising:
an integrated circuit comprising a plurality of superconducting devices, and at least one structure configured to trap a vortex;
a plurality of control lines configured to produce heat and magnetic fields which alter a pinning of the trapped vortex in the at least one structure and induce a Lorenz force to relocate the trapped vortex; and
a control configured to generate a timed sequence of control current pulses in plurality of the control lines, adapted to reduce a pinning of the trapped vortex to the at least one structure and sweep the trapped vortex away from the at least one structure using the induced Lorenz force.
